(19) United States
(12) Patent Application Publication
(10) Pub. No.: US 2013/0258618 A1
(43) Pub. Date: Oct. 3, 2013

(54) HIGH FREQUENCY MODULE

(71) Applicant: KABUSHIKI KAISHA TOSHIBA, Tokyo (JP)

(72) Inventor: Koichiro GOMI, Kanagawa-ken (JP)

(73) Assignee: Kabushiki Kaisha Toshiba, Tokyo (JP)

(21) Appl. No.: 13/788,033

(22) Filed: Mar. 7, 2013

(30) Foreign Application Priority Data
Mar. 30, 2012 (JP) 2012-082851

(51) Int. Cl. H05K 7/14

(52) U.S. Cl. CPC H05K 7/1422
USPC 361/752

(57) ABSTRACT

A module has a circuit board having a through-hole which separates a transmitter for transmitting the high frequency signal and a receiver for receiving the high frequency signal, both on the circuit board. The circuit board includes an insulating layer and a wiring layer. The wiring layer is formed in the ends of the insulating layer. A cover shields the transmitter and the receiver and has a partition part.

The partition part is electrically connected with the wiring layer and has a groove portion communicating with the through-hole, and is electrically connected with the wiring layer at the periphery of the through-hole. The depth of the groove portion L from a contact surface with the wiring layer satisfies

L=n×λ/2

Where, n is a natural number and λ is a wavelength of the high-frequency signal.

### CROSS-REFERENCE TO RELATED APPLICATIONS

This application is based upon and claims the benefit of priority from the prior Japanese Patent Application No. 2012-82851, filed on Mar. 30, 2012; the entire contents of which are incorporated herein by reference.

### FIELD

Embodiments described herein relate generally to a high frequency module.

### BACKGROUND

In recent years, a 1˜30 GHz microwave and a 30˜300 GHz millimeter wave are used for communicating information. Attention is attracted to, for example, a mass communications system and a system using a high frequency signal of an in-vehicle radar system etc.

In a high frequency module mounted on the system using the high frequency signal, a receiving performance of a receiving circuit is deteriorated since a transmitter wave oscillated from a transmitting circuit and/or an unnecessary wave from the outside may mixed into the receiving circuit. Therefore, it is usually provided such shielding that provides a metallic cover between the transmitting circuit and receiving circuit, and covering the transmitting circuit and receiving circuit to prevent from mixing the transmitter wave and/or the unnecessary wave.

However, it is difficult to secured shielding performance, because of insufficient contact of a shield cover provided between the transmitting circuit and the receiving circuit with a substrate on which the transmitting circuit and the receiving circuit are provided.

### BRIEF DESCRIPTION OF THE DRAWINGS

FIG. 1 is a schematic cross-sectional view illustrating a high frequency module according to a first embodiment;

FIG. 2 is a schematic cross-sectional view illustrating a high frequency module according to a second embodiment;

FIG. 3 is a schematic cross-sectional view illustrating a high frequency module according to a third embodiment;

### DETAILED DESCRIPTION

Reference will now be made in detail to the present embodiment of the invention, an example of which is illustrated in the accompanying drawings. Wherever possible, the same reference numbers will be used throughout the drawings to refer to the same or like parts.

According to one embodiment, high frequency module, includes a frame, a circuit board with a through-hole, comprising an insulating layer and a wiring layer, the wiring layer being arranged to cover the ends of the insulating layer and the periphery of the through-hole, the wiring layer being electrically connected to the frame, a first circuit and the second circuit provided on the circuit board being separated by the through-hole, the first circuit transmitting a high-frequency signal to outside, the second circuit receiving a high-frequency signal from the outside, a cover to shield over the first circuit and the second circuit, the cover being electrically connected with the wiring layer at the end of the insulating layer, the cover having a partition part for shielding the second circuit from the first circuit, the partition part being electrically connected with the wiring layer in the periphery of the through-hole at a contact surface, wherein the partition part has a groove portion to communicate with the through-hole and the groove portion has a depth L from the contact surface, the depth L satisfy a formula of L=n×λ/2 where n is a natural number, λ is a wavelength of the high-frequency signal.

According to one embodiment, high frequency module, includes a frame, a circuit board having a through-hole, comprising an insulating layer and a wiring layer, the wiring layer being arranged to cover the ends of the insulating layer and the periphery of the through-hole, the wiring layer being electrically connect with the frame, a first circuit and a second circuit provided on the circuit board, the first circuit transmitting a high-frequency signal to outside, the second circuit receiving the high-frequency signal from the outside, the first circuit and the second circuit being separated by the through-hole, a cover to shield over the first circuit and the second circuit, the cover being electrically connected with the wiring layer at the end of the insulating layer, the cover having a partition part for shielding the second circuit from the first circuit, the partition part being electrically connected with the wiring layer at a contact surface in the periphery of the through-hole, wherein a groove portion comprising the through-hole, an one end of the groove portion being closed at a surface of the frame, and the groove portion has a depth L from the contact surface via the through-hole to the surface of the frame, the depth L satisfy a formula of L=n×λ/2 where n is a natural number, λ is a wavelength of the high-frequency signal.

### First Embodiment

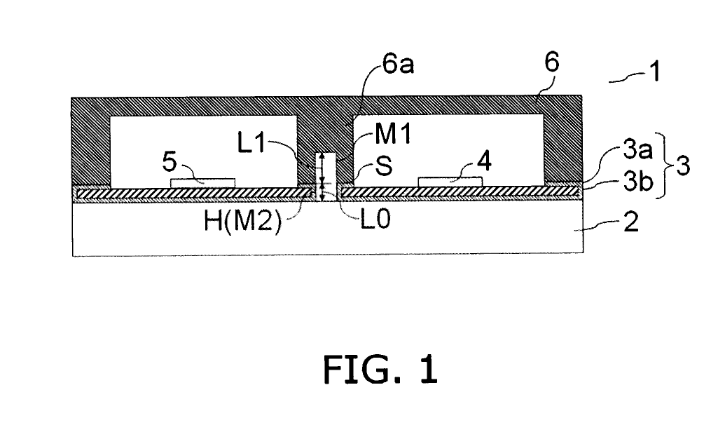

As shown in FIG. 1, a high frequency module 1 according to a first embodiment includes a frame 2, a circuit board 3, a transmitting circuit 4, a receiving circuit 5, and a cover 6 for shielding.

The frame 2 is tabular and formed from metal. The frame 2 supports the circuit board 3. Although the frame 2 is formed from metal in this embodiment, the frame 2 is not limited to it, but may use resin material having a metal-plated surface.

The circuit board 3 is provided on the frame 2 and includes a wiring layer 3a, a insulating layer 3b, and a through-hole H. Moreover the transmitting circuit 4 and the receiving circuit 5 are formed on the circuit board 3. The through-hole H is arranged between the transmitting circuit 4 and the receiving circuit 5, the high-frequency signal which occurs from the transmitting circuit 4 can control being spread to receive the circuit 5 through the insulating layer 3b.

The wiring layer 3a is arranged to contact with the frame 2. The wiring layer 3a covers at least one surface of the insulating layer 3b, and also covers ends of the insulating layer 3b. Moreover, the wiring layer 3a is formed on an inner surface of the through-hole H, and is formed on the insulating layer 3b of the periphery of the through-hole H. Thus the wiring layer 3a covers the inner surface of the through-hole H and covers the insulating layer 3b of the periphery of the through-hole H, the wiring layer 3a becomes possible to cause a grand pattern to form. The insulating layer 3b is made from insulating resin.

The transmitting circuit 4 (the first circuit) is arranged on the circuit board 3, and is a circuit for transmitting a high-frequency signal to the outside. And the receiving circuit 5 (the second circuit) is a circuit for receiving the high-frequency signal sent from the outside. Moreover, the transmitting circuit 4 and the receiving circuit 5 are separated by the through-hole H.

The cover 6 is arranged to be electrically connected to the wiring layer 3a, which is formed in the end of the circuit board 3 and formed the periphery of the through-hole H. And the cover 6 is arranged so that the transmitting circuit 4 and the receiving circuit 5 are covered. Moreover, the cover 6 has a partition part 6a which is arranged for shielding the transmitting circuit 4 and the receiving circuit 5. The partition part 6a suppresses the high-frequency signal from the transmitting circuit 4 to be received by the receiving circuit 5. The partition part 6a is electrically connected to the periphery of the through-hole H. Conductive metal material is preferable as the material of the cover 6. Although the cover 6 is formed from conductive metal, it is not limited to it but the cover 6 may be made of the resin material having a metal-plated surface.

The partition part 6a of the cover 6 has a first groove portion M1 which communicates with the through-hole H. One end of the first groove portion M1 is closed. The partition part 6a has opening from the contact surface S of the wiring layer 3a to the other end of the first groove portion M1, and is formed so that the section is the shape of type of cannel. Moreover, the first groove portion M1 is formed in the depth direction.

The first groove portion M1 has a depth L1 which is the depth from a contact surface S. The contact surface S is on a plane where the wiring layer 3a is arranged in the periphery of the through-hole H of the circuit board 3 and the cover 6 touches to the end of the first groove portion M1. The depth L1 of the first groove portion M1 is formed so as to satisfy the following formula, wherein a depth of a groove is set to L 1, a natural number is set to n and a high-frequency signal is set to λ₁.

L1=n×λ₁/2 (1)

The reason for forming the first groove portion M1 in the partition part 6a to have the depth shown by the formula (1) is for securing shielding performance by bringing the electric impedance between a cover and a upper surface pattern of the substrate close to 0, and not by securing connection of the cover and the upper surface pattern of the substrate using mechanical contact.

The electric impedance Zᵢₙ of the first groove portion M1 seen from the contact surface S which is the plane where the wiring layer 3a and the cover 6 touch is shown by the following formula, wherein the imaginary unit is indicated by j, a characteristic impedance is indicated by Z₀ and a phase constant is indicated by β.

Zᵢₙ=j Z₀ tan βL≈j Z₀ tan(2nL1/λ₁) (2)

In order to reach the electric impedance Zᵢₙ of the formula (2) to 0, the depth L1 of the groove portion is close to or is satisfied with the formula (1).

Therefore, the depth of the first groove portion M1 is formed so that the depth L1 is satisfied with the formula (1). Thereby, the first groove portion M1 has a function equivalent to a waveguide, high shielding performance is securable.

The impedance of the through-hole H can be added in parallel with the first groove portion M1. When the impedance of the through-hole H is large and the impedance of the first groove portion M1 is low enough, the impedance of the first groove portion M1 becomes dominant. However, when the impedance of the through-hole H is low enough, impedance of the first groove portion M1 and impedance of the through-hole H can be made parallel. The second groove portion M2 being formed with the through-hole H and the frame 2. Thereby, when the depth L0 is from the contact surface where the wiring layer 3a and the cover being touched to the surface where the case and the wiring layer 3a, the second groove portion M2 is close to or is satisfied with the formula (3).

L0=n×λ₁/2 (3)

Forming the second groove portion M2 is close to or is satisfied with the formula (3), the second groove portion has same effect as the first groove portion M1 and the high frequency module has higher shielding performance. The high-frequency signal λ₂ is different the high-frequency signal λ₁, the high-frequency signal λ₂ may apply the high-frequency signal λ₁ about the formula (3). Thereby the high frequency module can respond to a plurality of wavelengths. And the high frequency module with higher shielding performance can be offered.

According to the high frequency module of this embodiment, the grand pattern of the circuit board 3 and the cover 6 are connected electrically. The first groove portion M1 is formed in the partition part 6a of the cover 6, and the first groove portion M1 is formed so as to have the depth of L1=n×λ₁/2. Therefore, even if contact between the wiring board and the cover are insufficient, shielding performance is securable by the wiring board and the cover are connected electrically bringing the electric impedance close to 0. As a result, the high frequency module has higher shielding performance.

### Second Embodiment

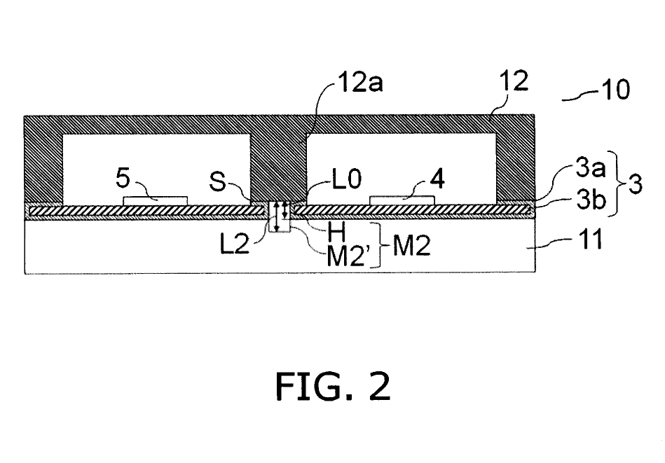

FIG. 2 shows a high frequency module according to a second embodiment. With this embodiment, the groove portion is formed in the frame, which is different from the first embodiment wherein the groove portion is formed in the partition part of the cover. For other element which is the same as that of the first embodiment, explanation is omitted.

A groove portion M2′ in a frame 11 is formed to communicate with the through-hole H of the circuit board 3. The second groove portion M2 being formed with the through-hole H and the groove portion M2′. The depth L0 of the through-hole H may be close to or is satisfied with the formula (3), the depth L0 may not be close to or is satisfied with the formula (3). The one end of the groove portion M2′ of the frame 11 is closed, thereby the one end of the groove portion M2 is closed. The second groove portion M2 is formed so that the depth L2 satisfies the formula (4), the depth L2 is from the contact surface S which is a plane where the wiring layer 3a of the circuit board 3 and a cover 12 touch to the other end of the second groove portion M2. That is, the depthL2 which is the through-hole H of the circuit board 3 and the end of the groove portion M2′ of the frame11 is formed so that the formula (4) is satisfied.

L2=n×λ₁/2 (4)

The cover 12 has a partition part 12a which is formed between the transmitting circuit 4 and the receiving circuit 5, and the cover 12 is arranged to cover the transmitting circuit 4 and the receiving circuit 5. And the cover 12 is electrically connected with the wiring layer 3a formed in the end of the circuit board 3 and the periphery of the through-hole H.

Thereby, the depthL2 which is the through-hole H of the circuit board 3 and the end of the groove portion M2′ of the frame11 is formed so that the formula (4) is satisfied, the frame 11 is electrically connected with the circuit board 3, and electric impedance closes to 0. As a result, the through-hole H and the frame 11 plays the same role in the cover 6 of the first embodiment, and has the same effect as the first embodiment. When the depth L0 of the through-hole H of the circuit board 3 is satisfied with the formula (4), the electric impedance of the through-hole H can reach to 0. Thereby the groove portion M2′ of the frame 11 is not necessary to form. The second groove portion M2 being formed with through-hole H and the case 2 of the first embodiment, the second groove portion M2 can acquire the same effect as the first embodiment.

According to the high frequency module of this embodiment, the grand pattern of the circuit board 3 and the cover 12 are connected electrically. The second groove portion M2 is formed in the frame 11, and the depth which is from the contact surface S to the end of the second groove, is formed so as to satisfy the formula (4). Therefore, the high frequency module has higher shielding performance.

### Third Embodiment

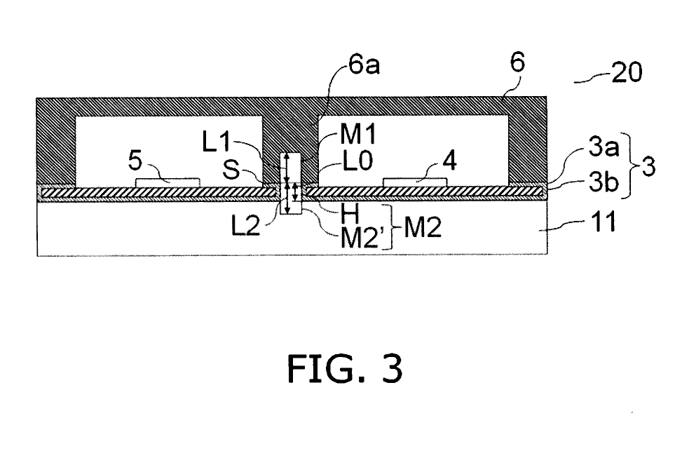

FIG. 3 shows a high frequency module according to a third embodiment. With this embodiment, a high frequency module 20 is adopted to have both of the cover 6 of the first embodiment, and the frame 11 of the second embodiment. The high frequency module 20 in case the through hole H is not satisfied with formula (3) but shields two of the high frequency signals in different wavelengths. Thereby, in order to shield two of the high frequency signals in different wavelengths, the depth L1 of the cover 6 in which the first groove portion M1 is formed satisfies with formula (1), and also the depth L2 which is the through-hole H of the circuit board 3 and the end of the groove portion M2′ of the frame11 is formed so that the formula (5) is satisfied.

L2=n×λ₂/2 (5)

That is, the first groove portion M1 and the second groove portion M2 are formed in the different depths. Thereby the high frequency module can respond to a plurality of wavelengths. And the high frequency module with higher shielding performance can be offered.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A high frequency module, comprising:
a frame;
a circuit board with a through-hole, comprising an insulating layer and a wiring layer, the wiring layer being arranged to cover the ends of the insulating layer and the periphery of the through-hole, the wiring layer being electrically connected to the frame;
a first circuit and the second circuit provided on the circuit board being separated by the through-hole, the first circuit transmitting a high-frequency signal to outside, the second circuit receiving a high-frequency signal from the outside; and
a cover to shield over the first circuit and the second circuit, the cover being electrically connected with the wiring layer at the end of the insulating layer, the cover having a partition part for shielding the second circuit from the first circuit, the partition part being electrically connected with the wiring layer in the periphery of the through-hole at a contact surface,
wherein,
the partition part has a groove portion to communicate with the through-hole and the groove portion has a depth L from the contact surface,
the depth L satisfy a formula of
L=n×λ/2
where n is a natural number, λ is a wavelength of the high-frequency signal.

2. The module according to claim 1, wherein
an other groove portion comprise the through-hole, an one end of the other groove portion being closed at a surface of the frame,
the other groove portion has a depth L from the contact surface via the through-hole to the surface of the frame,
the depth L satisfy a formula of
L=n×λ/2
where n is a natural number, λ is a wavelength of the high-frequency signal.

3. The module according to claim 2, wherein
the frame has an other groove portion communicating with the through-hole.

4. The module according to claim 2, wherein
the depth of the groove portion which is formed in the partition part is different from the depth of the groove portion which is formed in the through-hole and the frame, and being formed so that the formula which is the wavelength of different high frequency is satisfied.

5. High frequency module, comprising:
a frame;
a circuit board having a through-hole, comprising an insulating layer and a wiring layer, the wiring layer being arranged to cover the ends of the insulating layer and the periphery of the through-hole, the wiring layer being electrically connect with the frame;
a first circuit and a second circuit provided on the circuit board, the first circuit transmitting a high-frequency signal to outside, the second circuit receiving the high-frequency signal from the outside, the first circuit and the second circuit being separated by the through-hole; and
a cover to shield over the first circuit and the second circuit, the cover being electrically connected with the wiring layer at the end of the insulating layer, the cover having a partition part for shielding the second circuit from the first circuit, the partition part being electrically connected with the wiring layer at a contact surface in the periphery of the through-hole;
wherein,
a groove portion comprising the through-hole, an one end of the groove portion being closed at a surface of the frame, and the groove portion has a depth L from the contact surface via the through-hole to the surface of the frame,
the depth L satisfy a formula of
L=n×λ/2
where n is a natural number, λ is a wavelength of the high-frequency signal.

6. The module according to claim 5, wherein
the frame has an other groove portion communicating with the through-hole,

7. A high frequency module, comprising:
a frame;
a circuit board with a through-hole, comprising an insulating layer and a wiring layer, the wiring layer being arranged to cover the ends of the insulating layer and the periphery of the through-hole, the wiring layer being electrically connected to the frame;
a first circuit and the second circuit provided on the circuit board being separated by the through-hole, the first circuit transmitting a high-frequency signal to outside, the second circuit receiving a high-frequency signal from the outside; and
a cover to shield over the first circuit and the second circuit, the cover being electrically connected with the wiring layer at the end of the insulating layer, the cover having a partition part for shielding the second circuit from the first circuit, the partition part being electrically connected with the wiring layer in the periphery of the through-hole at a contact surface,
wherein,
a groove portion is provide in at least one of the partition part, or the through-hole and the frame, the groove portion has a depth L from the contact surface,
the depth L satisfy a formula of
L=n×λ/2
where n is a natural number, λ is a wavelength of the high-frequency signal.
